(19) United States
(12) Patent Application Publication
(10) Pub. No.: US 2026/0333755 A1
(43) Pub. Date: Oct. 22, 2026

(54) SEMICONDUCTOR DEVICE AND METHOD FOR MANUFACTURING SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Kensuke NAGATA, Nisshin-shi (JP); Ryota SUZUKI, Nisshin-shi (JP)

(21) Appl. No.: 19/648,592

(22) Filed: Apr. 15, 2026

(30) Foreign Application Priority Data
Apr. 18, 2025 (JP) 2025-068773

(51) Int. Cl. H10D 30/66; H10D 30/01; H10D 62/10; H10D 64/23; H10D 64/62; H10D 62/60

(52) U.S. Cl. CPC H10D 30/668; H10D 30/0297; H10D 62/126; H10D 64/252; H10D 64/62; H10D 62/102; H10D 62/60

(57) ABSTRACT

A semiconductor device includes: a semiconductor layer having a first main surface and a second main surface, in which a gate trench and a dummy trench are formed in the first main surface; a trench gate including a gate electrode embedded in the gate trench; an interlayer insulating film disposed on the gate electrode and embedded in the gate trench; a dummy trench gate including a dummy electrode embedded in the dummy trench; and a surface electrode in contact with the first main surface of the semiconductor layer as well as the dummy electrode embedded in the dummy trench. A top surface of the dummy electrode is located above a top surface of the gate electrode in a thickness direction of the semiconductor layer.

### CROSS REFERENCE TO RELATED APPLICATION

The present application claims the benefit of priority from Japanese Patent Application No. 2025-068773 filed on Apr. 18, 2025, the entire contents of which are incorporated herein by reference.

### TECHNICAL FIELD

The present disclosure relates to a semiconductor device and a method for manufacturing the semiconductor device.

### BACKGROUND

As a related art, there is a semiconductor device in which a source trench is formed between adjacent trench gates. A source electrode is disposed in the source trench. In the semiconductor device having such a structure, a channel resistance and a gate input capacitance can be adjusted.

### SUMMARY

According to an aspect of the present disclosure, a semiconductor device may include: a semiconductor layer having a first main surface and a second main surface opposite to the first main surface in a thickness direction of the semiconductor layer, a gate trench and a dummy trench being formed in the first main surface; a trench gate including a gate electrode embedded in the gate trench; an interlayer insulating film disposed on the gate electrode and embedded in the gate trench; a dummy trench gate including a dummy electrode embedded in the dummy trench; and a surface electrode disposed in contact with the first main surface of the semiconductor layer and the dummy electrode embedded in the dummy trench. A top surface of the dummy electrode may be located above a top surface of the gate electrode.

### BRIEF DESCRIPTION OF THE DRAWINGS

Objects, features and advantages of the present disclosure will become more apparent from the following detailed description made with reference to the accompanying drawings, in which like parts are designated by like reference numbers and in which:

FIG. 1 is a schematic longitudinal cross-sectional view of a main portion of a semiconductor device according to an embodiment, taken along a line I-I in FIG. 2;

FIG. 2 is a schematic transverse cross-sectional view of the main portion of the semiconductor device taken along a line II-II in FIG. 1;

FIG. 3 is a schematic longitudinal cross-sectional view of a main portion of a semiconductor device according to a modified example, illustrating a modified layout of trench gates and dummy trench gates, taken along a line III-III in FIG. 4;

FIG. 4 is a schematic transverse cross-sectional view of the main portion of the semiconductor device according to the modified example, illustrating the modified layout of trench gates and dummy trench gates, taken along a line IV-IV in FIG. 3;

FIG. 5 is a schematic longitudinal cross-sectional view of a main portion of a semiconductor device according to a modified example, illustrating a modified layout of trench gates and dummy trench gates, taken along a line V-V in FIG. 6;

FIG. 6 is a schematic transverse cross-sectional view of the main portion of the semiconductor device according to the modified example, illustrating the modified layout of trench gates and dummy trench gates, taken along a line VI-VI in FIG. 5;

FIG. 7 is a schematic longitudinal cross-sectional view of a main portion of a semiconductor layer in one step of a method for manufacturing the semiconductor device shown in FIGS. 1 and 2;

FIG. 8 is a schematic longitudinal cross-sectional view of the main portion of the semiconductor layer in one step of the method for manufacturing the semiconductor device shown in FIGS. 1 and 2;

FIG. 9 is a schematic longitudinal cross-sectional view of the main portion of the semiconductor layer in one step of the method for manufacturing the semiconductor device shown in FIGS. 1 and 2;

FIG. 10 is a schematic longitudinal cross-sectional view of the main portion of the semiconductor layer in one step of the method for manufacturing the semiconductor device shown in FIGS. 1 and 2;

FIG. 11 is a schematic longitudinal cross-sectional view of the main portion of the semiconductor layer in one step of the method for manufacturing the semiconductor device shown in FIGS. 1 and 2;

FIG. 12 is a schematic longitudinal cross-sectional view of the main portion of the semiconductor layer in one step of the method for manufacturing the semiconductor device shown in FIGS. 1 and 2;

FIG. 13 is a schematic longitudinal cross-sectional view of the main portion of the semiconductor layer in one step of the method for manufacturing the semiconductor device shown in FIGS. 1 and 2;

FIG. 14 is a schematic longitudinal cross-sectional view of the main portion of the semiconductor layer in one step of the method for manufacturing the semiconductor device shown in FIGS. 1 and 2;

FIG. 15 is a schematic longitudinal cross-sectional view of the main portion of the semiconductor layer in one step of the method for manufacturing the semiconductor device shown in FIGS. 1 and 2;

FIG. 16 is a schematic longitudinal cross-sectional view of a main portion of a semiconductor device according to a modified example, illustrating a modified trench width of a dummy trench;

FIG. 17 is a schematic longitudinal cross-sectional view of a main portion of a semiconductor device according to a modified example, illustrating a modified trench width of a dummy trench;

FIG. 18 is a schematic longitudinal cross-sectional view of a main portion of a semiconductor device according to a modified example, illustrating a modified trench depth of a dummy trench;

FIG. 19 is a schematic longitudinal cross-sectional view of a main portion of a semiconductor device according to a modified example, illustrating a modified trench depth of a dummy trench;

FIG. 20 is a schematic longitudinal cross-sectional view of a main portion of a semiconductor device according to a modified example, illustrating a modified structure of a source electrode; and

FIG. 21 is a schematic perspective view of a main portion of a semiconductor device according to an embodiment, in a state where a source electrode is removed.

### DETAILED DESCRIPTION

As a related art, there is a semiconductor device having a source trench between adjacent trench gates, and a source electrode is disposed in the source trench. In such a semiconductor device having such a structure, it is possible to adjust a channel resistance and a gate input capacitance.

In this specification, the source trench is referred to as a “dummy trench”, and an electrode disposed in the dummy trench is referred to as a “dummy electrode”. Further, a structure including the dummy electrode is referred to as a “dummy trench gate”.

In a semiconductor device, a contact portion having an electrical connection with a surface electrode is necessary in a region between adjacent trench gates. In the semiconductor device of the related art, a dummy trench gate is used as the contact portion. Therefore, in the semiconductor device of the related art, the dummy trench gate needs to be disposed in each region between adjacent trench gates, resulting in a decrease in layout flexibility. The present disclosure provides a technique capable of improving the layout flexibility of a trench gate and a dummy trench gate.

According to an aspect of the present disclosure, a semiconductor device may include: a semiconductor layer having a first main surface and a second main surface, in which a gate trench and a dummy trench are formed in the first main surface; a trench gate including a gate electrode embedded in the gate trench; an interlayer insulating film disposed on the gate electrode and embedded in the gate trench; a dummy trench gate including a dummy electrode embedded in the dummy trench; and a surface electrode disposed in contact with the first main surface of the semiconductor layer and the dummy electrode embedded in the dummy trench. A top surface of the dummy electrode may be located above a top surface of the gate electrode.

In such a semiconductor device, the interlayer insulating film is embedded in the gate trench. Therefore, a region of the first main surface of the semiconductor layer between adjacent trench gates can be in direct contact with the surface electrode. Accordingly, it is not necessary to arrange the dummy trench gate in each region between adjacent trench gates, and the dummy trench gate can be disposed as appropriate according to specifications. The semiconductor device described above has high layout flexibility of the trench gate and the dummy trench gate.

According to an aspect of the present disclosure, a method for manufacturing a semiconductor device may include: forming a gate trench and a dummy trench in a first main surface of a semiconductor layer having the first main surface and a second main surface; embedding a gate electrode in the gate trench and embedding a dummy electrode in the dummy trench, so that a top surface of the dummy electrode is located above a top surface of the gate electrode; and embedding an interlayer insulating film in the gate trench.

According to such a method, a semiconductor device having high layout flexibility of the trench gate and the dummy trench gate can be manufactured.

Hereinafter, multiple embodiments of the present disclosure will be described with reference to the drawings. Note that, for components arranged repeatedly, reference numbers are attached only to a part of them for the purpose of clarifying the drawings. In addition, components common to semiconductor devices of different embodiments are denoted by the same reference numbers, and description thereof is not repeated.

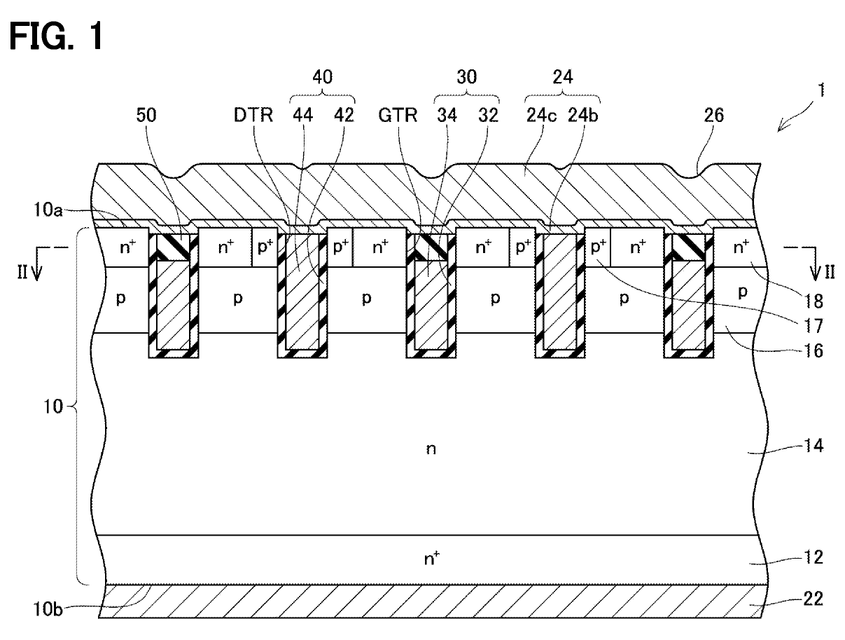

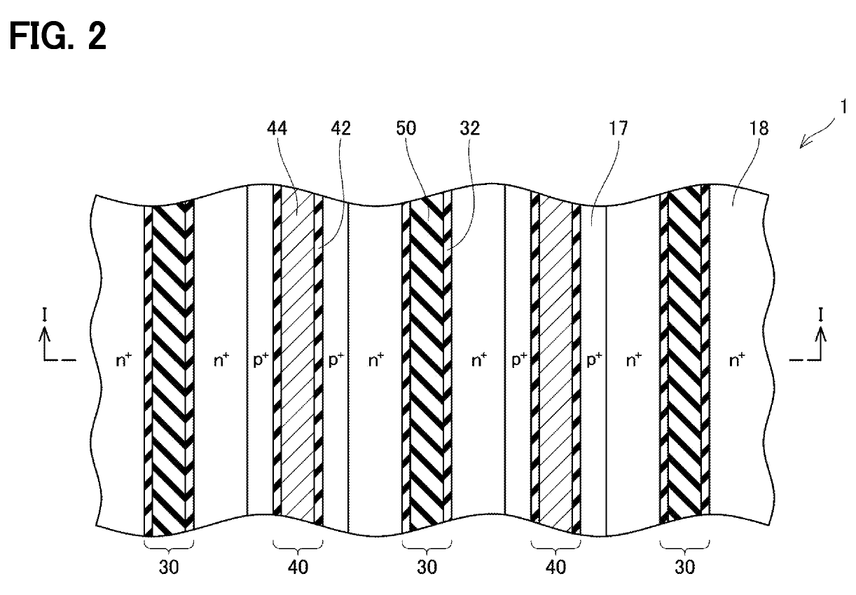

As shown in FIGS. 1 and 2, a semiconductor device 1 is a power device of a type referred to as an n-channel MOSFET (Metal Oxide Semiconductor Field Effect Transistor), and includes a semiconductor layer 10 having a first main surface 10a and a second main surface 10b. The material of the semiconductor layer 10 may be, for example, silicon carbide (SiC). Here, the first main surface 10a and the second main surface 10b are a pair of surfaces extending parallel to each other, among surfaces of the semiconductor layer 10, and are surfaces orthogonal to a thickness direction of the semiconductor layer 10. The first main surface 10a and the second main surface 10b are opposite to each other in the thickness direction of the semiconductor layer 10. Hereinafter, the structure of the semiconductor device 1 will be described in an orientation in which the first main surface 10a is an upper surface, the second main surface 10b is a lower surface, and the thickness direction of the semiconductor layer 10 is the vertical direction.

The semiconductor device 1 further includes a drain electrode 22 covering the second main surface 10b of the semiconductor layer 10, a source electrode 24 covering the first main surface 10a of the semiconductor layer 10, a plurality of trench gates 30 disposed in the semiconductor layer 10 at the first main surface 10a, and a plurality of dummy trench gates 40 disposed in the semiconductor layer 10 at the first main surface 10a. The semiconductor layer 10 includes an n⁺ type drain region 12, an n type drift region 14, a p type body region 16, a p⁺ type body contact region 17, and an n⁺ type source region 18.

The drain region 12 is a region disposed in a lower layer portion of the semiconductor layer 10, and is located at a position exposed on the second main surface 10b of the semiconductor layer 10. The drain region 12 contains an n type impurity at a high concentration and is in ohmic contact with the drain electrode 22. The drain region 12 may be a silicon carbide substrate for epitaxially growing the drift region 14, as will be described in a manufacturing method described later.

The drift region 14 is a region disposed so as to be in contact with an upper surface of the drain region 12, and is located between the drain region 12 and the body region 16. The concentration of an n type impurity contained in the drift region 14 is lower than the concentration of an n type impurity contained in the drain region 12. The drift region 14 may be formed, for example, by epitaxially growing from the upper surface of the drain region 12.

The body region 16 is a region disposed so as to be in contact with an upper surface of the drift region 14, and is located between the drift region 14 and the body contact region 17 and between the drift region 14 and the source region 18. The body region 16 is in contact with side surfaces of the trench gates 30 and the dummy trench gates 40. The body region 16 may be formed, for example, by performing ion implantation of a p type impurity (for example, aluminum) to the first main surface 10a of the semiconductor layer 10.

The body contact region 17 is a region disposed in an upper layer portion of the semiconductor layer 10 while being in contact with an upper surface of the body region 16, and is located at a position exposed on the first main surface 10a of the semiconductor layer 10. The body contact region 17 contains a p type impurity at a high concentration and is in ohmic contact with the source electrode 24. The arrangement of the body contact region 17 on the first main surface 10a of the semiconductor layer 10 is appropriately designed depending on specifications. The body contact region 17 may be disposed, for example, so as to be in contact with an upper portion of a side surface of the dummy trench gate 40. The body contact region 17 may be formed, for example, by performing ion implantation of a p type impurity (for example, aluminum) to the first main surface 10a of the semiconductor layer 10.

The source region 18 is a region disposed in an upper layer portion of the semiconductor layer 10 while being in contact with an upper surface of the body region 16, and is located at a position exposed on the first main surface 10a of the semiconductor layer 10. The source region 18 contains an n type impurity at a high concentration and is in ohmic contact with the source electrode 24. The arrangement of the source region 18 on the first main surface 10a of the semiconductor layer 10 is appropriately designed depending on specifications. The source region 18 may be disposed, for example, so as to be in contact with an upper portion of a side surface of the trench gate 30. The source region 18 may be formed, for example, by performing ion implantation of an n type impurity (for example, nitrogen) to the first main surface 10a of the semiconductor layer 10.

The trench gate 30 is disposed in a gate trench GTR that extends from the first main surface 10a, penetrates the source region 18 and the body region 16, and reaches the drift region 14 in the semiconductor layer 10. A plurality of the trench gates 30 may be arranged, for example, in a stripe shape when the semiconductor layer 10 is viewed in plan, that is, in a plan view when the semiconductor layer 10 is viewed in the thickness direction. Hereinafter, the plan view when the semiconductor layer 10 is viewed in the thickness direction will be simply referred to as the plan view of the semiconductor layer 10. In the plan view of the semiconductor layer 10, the plurality of trench gates 30 may extend along one direction (hereinafter referred to as a longitudinal direction of the trench gates 30) and may be disposed spaced apart from each other in a direction orthogonal to the longitudinal direction. Further, the trench gate 30 may be divided at a part in the longitudinal direction, and the dummy trench gate 40 may be disposed in a region between the divided trench gates 30.

The trench gate 30 includes a gate insulating film 32 and a gate electrode 34. The gate insulating film 32 is in contact with side surfaces and a bottom surface of the gate trench GTR. The gate electrode 34 is disposed in the gate trench GTR, and a side surface and a bottom surface of the gate electrode 34 are covered with the gate insulating film 32. The gate electrode 34 is insulated from the semiconductor layer 10 by the gate insulating film 32. The gate electrode 34 may be, for example, made of polysilicon doped with an n type impurity at a high concentration.

The gate electrode 34 is disposed in a part of the gate trench GTR such that the top surface of the gate electrode 34 is located below the level of the first main surface 10a of the semiconductor layer 10 in the thickness direction. In other words, the gate electrode 34 is embedded within the gate trench GTR. An interlayer insulating film 50 is disposed in the gate trench GTR above the gate electrode 34. The interlayer insulating film 50 is disposed in an upper part of the gate trench GTR such that the top surface of the interlayer insulating film 50 is flush with the first main surface 10a of the semiconductor layer 10. Alternatively, the interlayer insulating film 50 is disposed in an upper part of the gate trench GTR such that the top surface of the interlayer insulating film 50 is located below the level of the first main surface 10a of the semiconductor layer 10. In other words, the interlayer insulating film 50 is embedded within the gate trench GTR. The gate electrode 34 is insulated from the source electrode 24 by the interlayer insulating film 50. A structure in which the interlayer insulating film 50 is embedded within the gate trench GTR is referred to as a self-aligned contact structure.

The dummy trench gate 40 is disposed in a dummy trench DTR that extends from the first main surface 10a, penetrates the body contact region 17 and the body region 16, and reaches the drift region 14 in the semiconductor layer 10. A plurality of the dummy trench gates 40 may be arranged, for example, in a stripe shape when the semiconductor layer 10 is viewed in plan. That is, in the plan view of the semiconductor layer 10, the plurality of dummy trench gates 40 may extend along one direction (hereinafter referred to as a longitudinal direction of the dummy trench gates 40) and may be disposed spaced apart from each other in a direction orthogonal to the longitudinal direction. Further, the dummy trench gate 40 may be divided at a part in the longitudinal direction, and the trench gate 30 may be disposed in a region between the divided dummy trench gates 40.

The dummy trench gate 40 includes a dummy insulating film 42 and a dummy electrode 44. The dummy insulating film 42 is in contact with a side surface and a bottom surface of the dummy trench DTR. The dummy electrode 44 is disposed in the dummy trench DTR, and a side surface and a bottom surface of the dummy electrode 44 are covered with the dummy insulating film 42. The dummy electrode 44 is separated from the semiconductor layer 10 by the dummy insulating film 42. The dummy electrode 44 may be, for example, made of polysilicon doped with an n type impurity at a high concentration.

The dummy electrode 44 is disposed in the dummy trench DTR such that the top surface of the dummy electrode 44 is flush with the first main surface 10a of the semiconductor layer 10, or such that the top surface of the dummy electrode 44 is located below the level of the first main surface 10a of the semiconductor layer 10. In other words, the dummy electrode 44 is embedded in the dummy trench DTR. The dummy electrode 44 is further disposed such that the top surface of the dummy electrode 44 is located above the level of the top surface of the gate electrode 34. The interlayer insulating film 50 is not disposed in the dummy trench DTR. Therefore, the top surface of the dummy electrode 44 is in contact with the source electrode 24.

The source electrode 24 is disposed so as to cover the first main surface 10a of the semiconductor layer 10. The source electrode 24 includes a silicide layer 24b, and a metal electrode layer 24c. The silicide layer 24b may be a layer thinner than the metal electrode layer 24c. The source electrode 24 is an example of the surface electrode.

The silicide layer 24b is disposed so as to cover the first main surface 10a of the semiconductor layer 10. The silicide layer 24b is disposed at positions in contact with the first main surface 10a of the semiconductor layer 10 and each of the dummy electrodes 44. The silicide layer 24b is in ohmic contact with the first main surface 10a of the semiconductor layer 10 and each of the dummy electrodes 44. The silicide layer 24b may be a silicide layer formed by silicidation of a single metal of titanium (Ti) or a titanium-containing compound such as titanium nitride (TiN).

The metal electrode layer 24c is disposed so as to cover the first main surface 10a of the semiconductor layer 10. The metal electrode layer 24c is a portion serving as a metal pad. On an upper surface of the metal electrode layer 24c, recesses 26 are formed at positions above the gate trenches GTR and the dummy trenches DTR. As will be described later, the depressed amount of each recess 26, that is, a maximum depth of each recess 26 is different between the recess 26 corresponding to the gate trench GTR and the recess 26 corresponding to the dummy trench DTR. The metal electrode layer 24c may be, for example, made of aluminum silicon (AlSi).

Next, the operation of the semiconductor device 1 will be described. When a positive voltage higher than that of the source electrode 24 is applied to the drain electrode 22 and a positive voltage higher than a threshold voltage is applied to the gate electrode 34, the semiconductor device 1 is turned on. At this time, an inversion layer serving as a channel is formed in the body region 16 in contact with the side surface of the trench gate 30. Electrons injected from the source region 18 are injected into the drift region 14 via the inversion layer of the body region 16, and further moved from the drift region 14 to the drain region 12. As a result, the semiconductor device 1 turns on. When the positive voltage applied to the gate electrode 34 falls below the threshold voltage, the inversion layer in the body region 16 disappears and the semiconductor device 1 turns off. In this manner, the semiconductor device 1 can perform a switching operation by controlling a current flowing through the inversion layer in accordance with the voltage applied to the gate electrode 34.

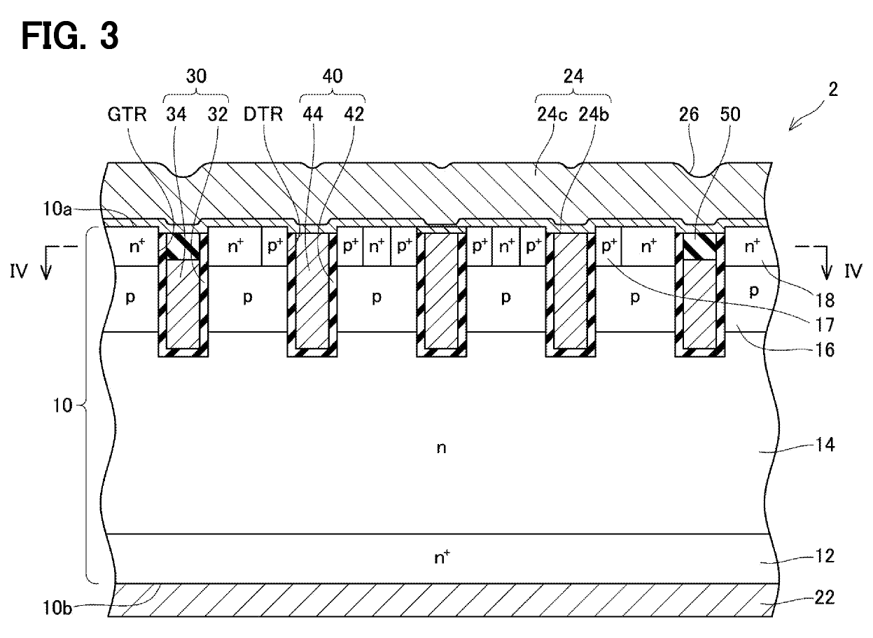

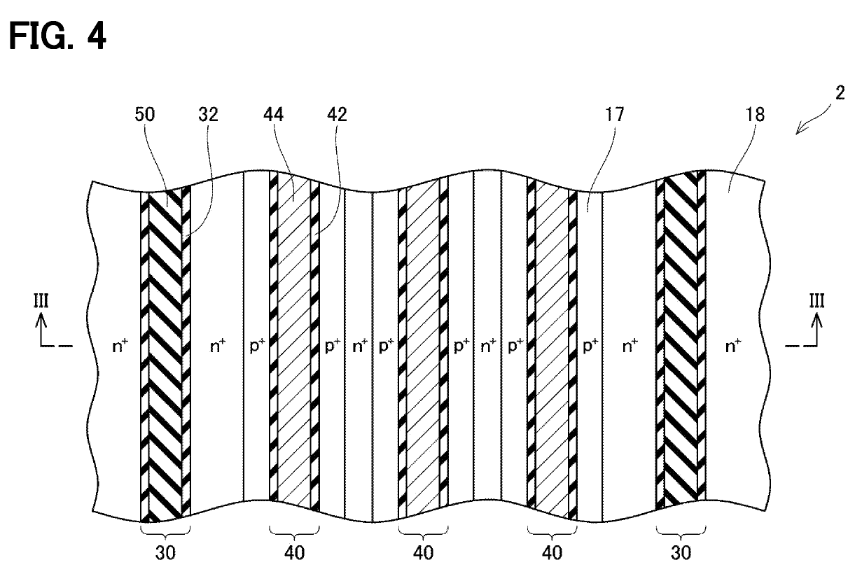

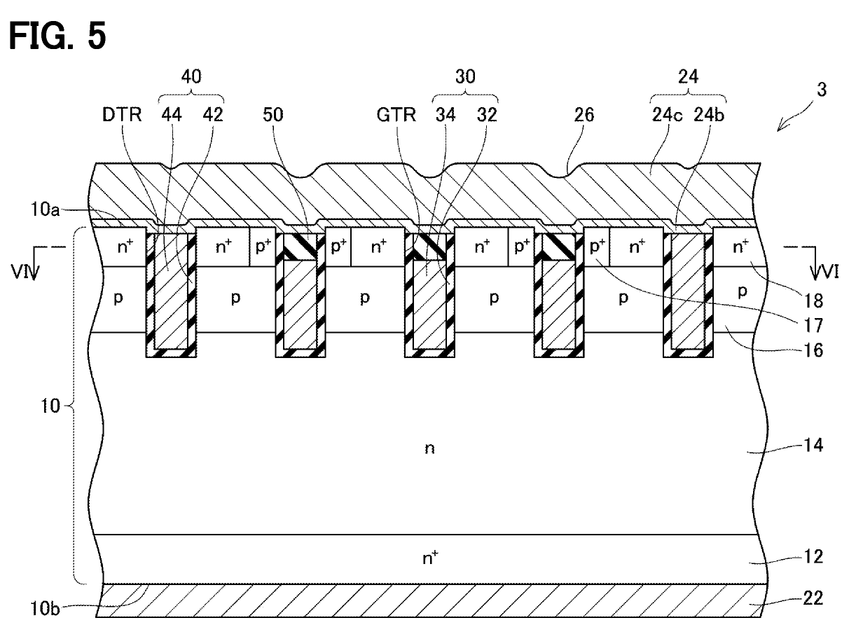

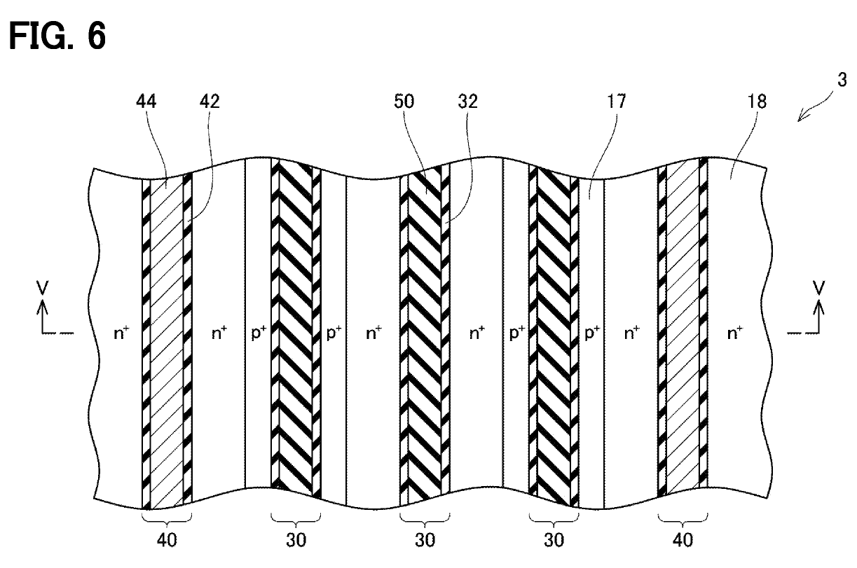

As described above, the semiconductor device 1 has the self-aligned contact structure. Therefore, the interlayer insulating film 50 is embedded in the gate trench GTR and is not disposed on the first main surface 10a of the semiconductor layer 10. Accordingly, the source electrode 24 can be directly in contact with the first main surface 10a of the semiconductor layer 10. Differently from the semiconductor device described as a related art, in the semiconductor device 1 of the embodiment, the dummy trench gate 40 is not used as a contact portion for electrically connecting the semiconductor layer 10 and the source electrode 24. Therefore, it is not necessary to arrange the dummy trench gate 40 in each of regions between adjacent trench gates 30, and the dummy trench gate 40 can be disposed as appropriate depending on specifications. For example, as in a semiconductor device 2 shown in FIGS. 3 and 4, when the semiconductor layer 10 is viewed in plan, that is, in the plan view of the semiconductor layer 10, two or more dummy trench gates 40 may be disposed between adjacent trench gates 30. For example, as in a semiconductor device 3 shown in FIGS. 5 and 6, when the semiconductor layer 10 is viewed in plan, that is, in the plan view of the semiconductor layer 10, two or more trench gates 30 may be disposed between adjacent dummy trench gates 40. As another example, the trench gates 30 and the dummy trench gates 40 may be alternately arranged. These are merely examples, and the layout of the trench gates 30 and the dummy trench gates 40 can be appropriately designed depending on specifications. The technique disclosed in this specification can improve the layout flexibility of the trench gates 30 and the dummy trench gates 40.

The source electrode 24 of the embodiment described above includes the silicide layer 24b containing titanium in a portion in contact with the dummy electrode 44. In a related art, nickel is generally used as the material of a silicide layer. In such a case, there is concern that particles may be generated due to an abnormal reaction between polysilicon, which is the material of the dummy electrode 44, and nickel. On the other hand, in the semiconductor device 1 of the embodiment, since the silicide layer 24b containing titanium is disposed above the dummy electrode 44, such particle generation is suppressed.

In the embodiment described above, the top surface of the dummy electrode 44 is located above the level of the top surface of the gate electrode 34. For example, in a case where the top surface of the dummy electrode 44 is at the same depth or lower than the top surface of the gate electrode 34, the depressed amount of the recess 26 on the upper surface of the source electrode 24 is larger in the recess 26 above the dummy trench DTR since the interlayer insulating film 50 is not embedded in the dummy trench DTR. Thus, there is a concern that a flatness of the source electrode 24 will be degraded. In a case where the top surface of the dummy electrode 44 is at the same depth or lower than the top surface of the gate electrode 34, the height of a step between the first main surface 10a of the semiconductor layer 10 and the top surface of the dummy electrode 44 is large since the interlayer insulating film 50 is not embedded in the dummy trench DTR. In this case, there is a concern that a split will be generated in the silicide layer 24b when the silicide layer 24b is formed. In the embodiment described above, the top surface of the dummy electrode 44 is located above the level of the top surface of the gate electrode 34. Therefore, it is possible to suppress an increase in the depressed amount of the recess 26 corresponding to the dummy trench DTR and to suppress generation of the split in the silicide layer 24b when the silicide layer 24b is formed. Moreover, in the embodiment described above, by adjusting the position of the top surface of the dummy electrode 44, the depressed amount of the recess 26 corresponding to the dummy trench DTR is smaller than the depressed amount of the recess 26 corresponding to the gate trench GTR. As a result, in the embodiment described above, the flatness of the source electrode 24 is improved, and the film formation of the silicide layer 24b can be improved.

### Method for Manufacturing Semiconductor Device 1

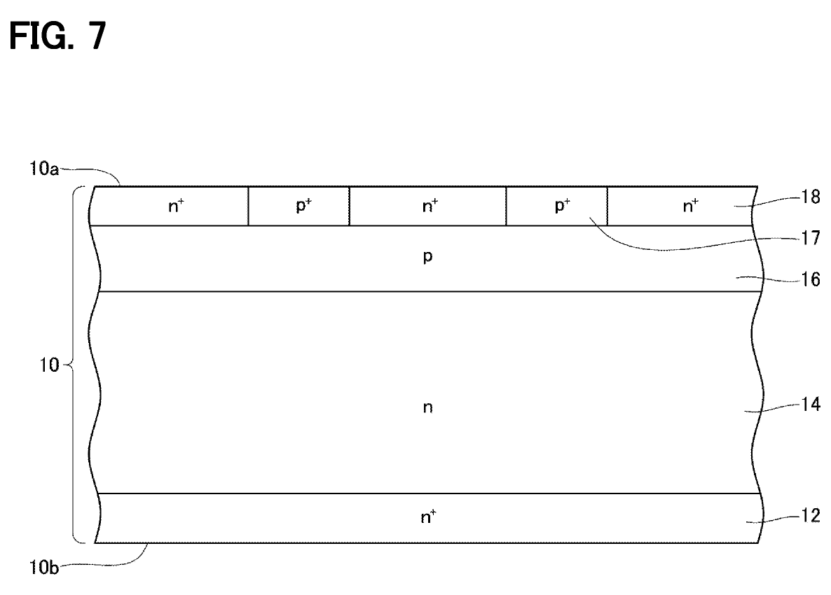

Next, a method for manufacturing the semiconductor device 1 will be described with reference to FIGS. 7-15.

First, as shown in FIG. 7, a semiconductor layer 10 in which a drain region 12, a drift region 14, a body region 16, a body contact region 17, and a source region 18 are stacked is prepared. This semiconductor layer 10 may be prepared, for example, by growing an epitaxial layer having a low concentration of n type impurity from an upper surface of the drain region 12 which is a silicon carbide substrate, and then ion-implanting an n type impurity and a p type impurity into an upper layer portion of the epitaxial layer to form the body region 16, the body contact region 17, and the source region 18.

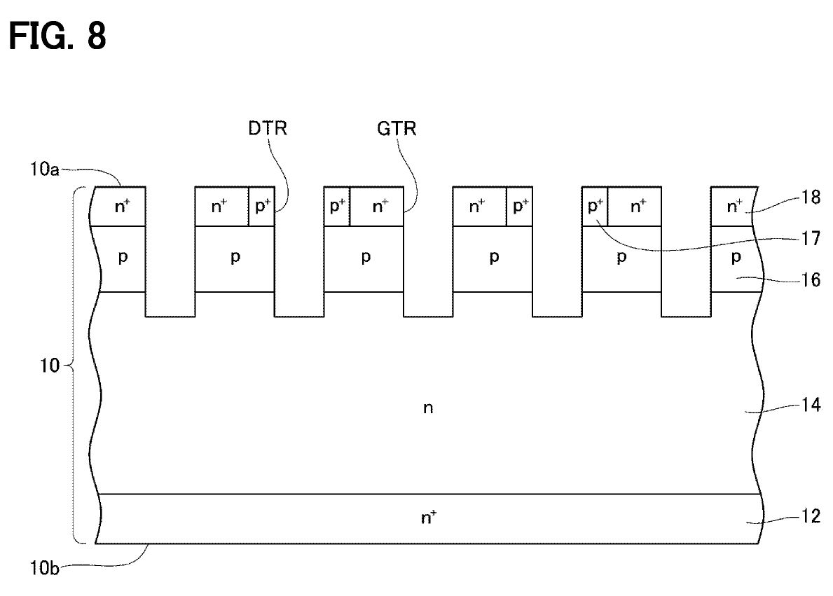

Next, as shown in FIG. 8, a gate trench GTR and a dummy trench DTR that extend from a first main surface 10a, penetrate the body region 16, and reach the drift region 14 are formed in the semiconductor layer 10, for example, using a dry etching technique. The gate trench GTR may be formed such that at least a part of its side surface is in contact with the source region 18. The dummy trench DTR may be formed such that at least a part of its side surface is in contact with the body contact region 17.

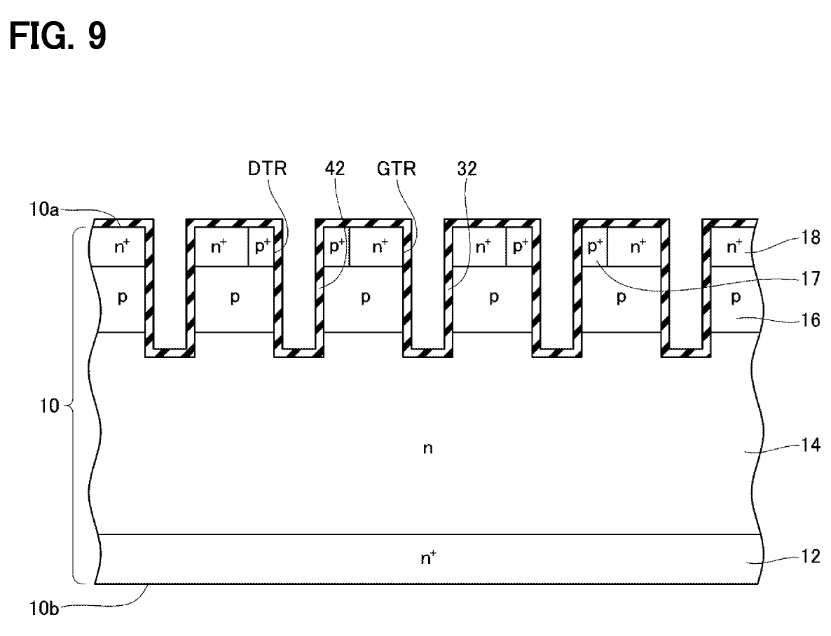

Next, as shown in FIG. 9, a silicon oxide film is formed, for example, using a chemical vapor deposition (CVD) method so as to cover the first main surface 10a of the semiconductor layer 10. The silicon oxide film is also formed on inner walls of the gate trench GTR and the dummy trench DTR. Thus, the gate insulating film 32 is formed on the side surface and the bottom surface of the gate trench GTR, and the dummy insulating film 42 is formed on the side surface and the bottom surface of the dummy trench DTR.

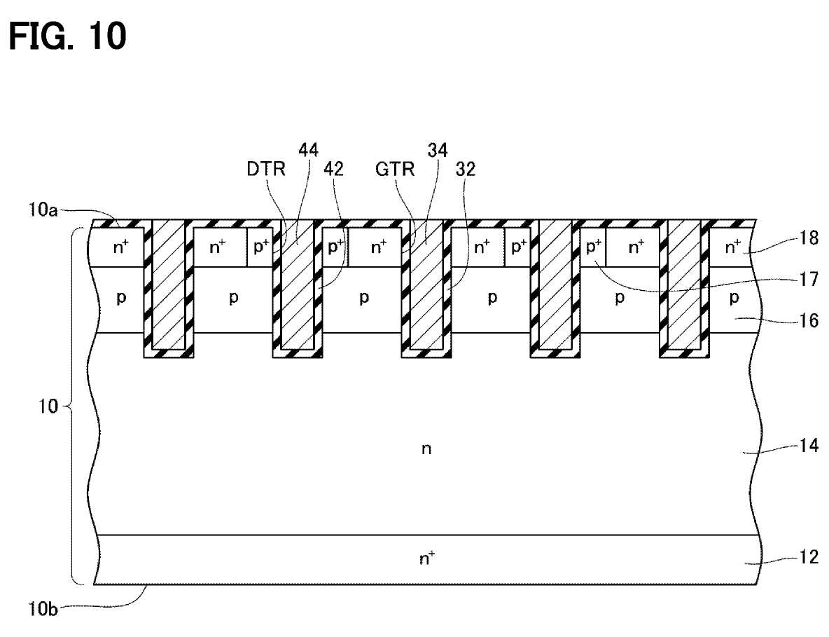

Next, as shown in FIG. 10, a polysilicon film doped with an n type impurity is formed, for example, using a CVD method so as to cover the first main surface 10a of the semiconductor layer 10. The polysilicon film is filled in the gate trench GTR and the dummy trench DTR. Next, an unnecessary portion of the polysilicon film formed above the first main surface 10a of the semiconductor layer 10 is removed by etch-back using an etching technique. As a result, the gate electrode 34 embedded in the gate trench GTR and the dummy electrode 44 embedded in the dummy trench DTR are formed.

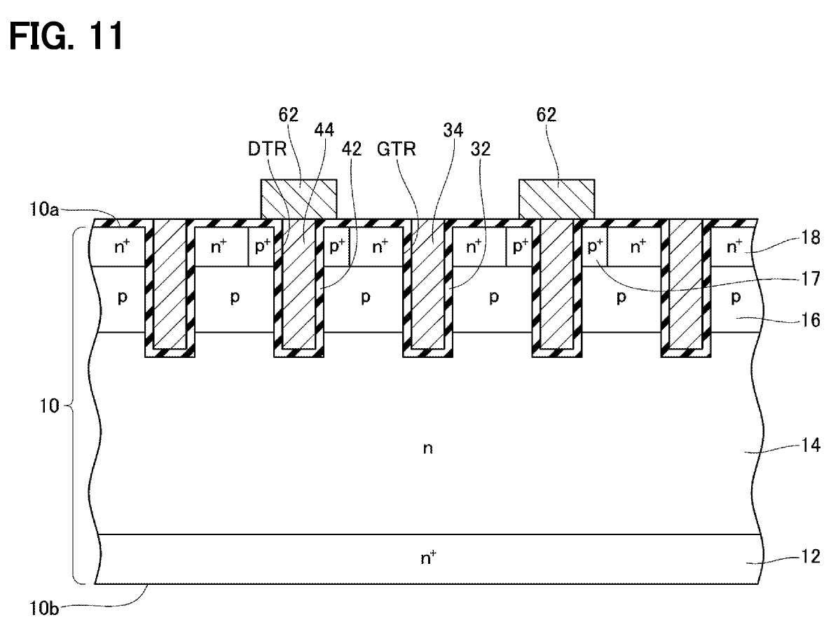

Next, as shown in FIG. 11, a mask 62 is formed on the first main surface 10a of the semiconductor layer 10, for example, using a photolithography technique. The mask 62 is patterned so as to cover the dummy electrode 44 and not to cover the gate electrode 34.

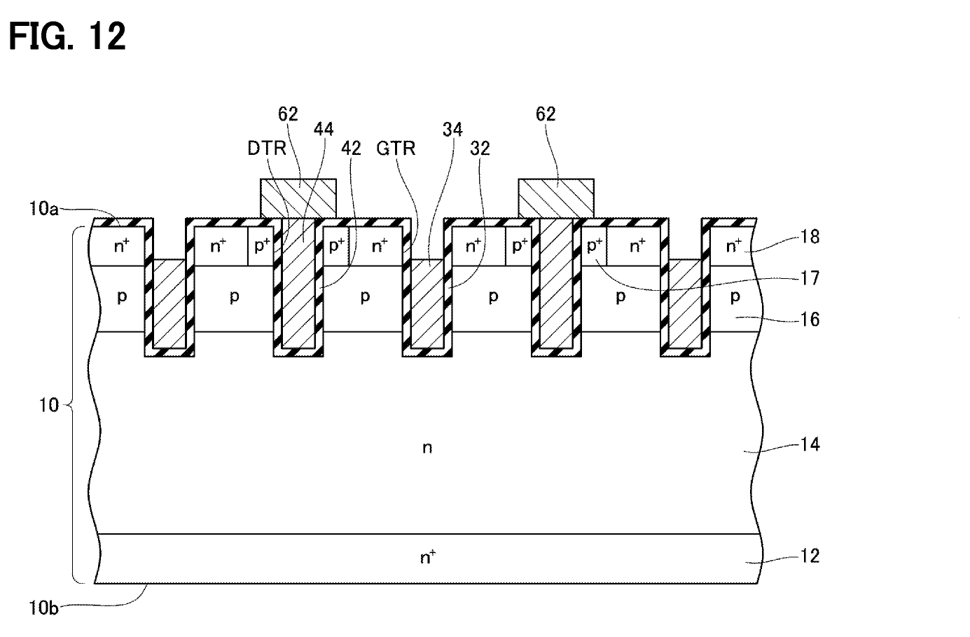

Next, as shown in FIG. 12, a portion of the gate electrode 34 embedded in the gate trench GTR is removed, for example, using a wet etching technique. After the portion of the gate electrode 34 is removed, the mask 62 is removed. By this removal, the top surface of the dummy electrode 44 is positioned above the level of the top surface of the gate electrode 34.

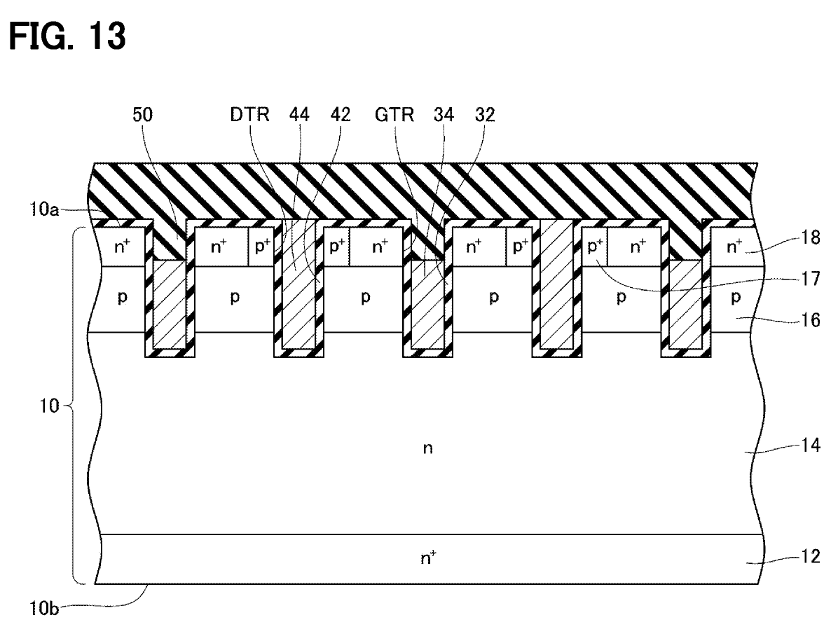

Next, as shown in FIG. 13, an interlayer insulating film 50 is formed, for example, using a CVD method so as to cover the first main surface 10a of the semiconductor layer 10. A part of the interlayer insulating film 50 is filled in the gate trench GTR.

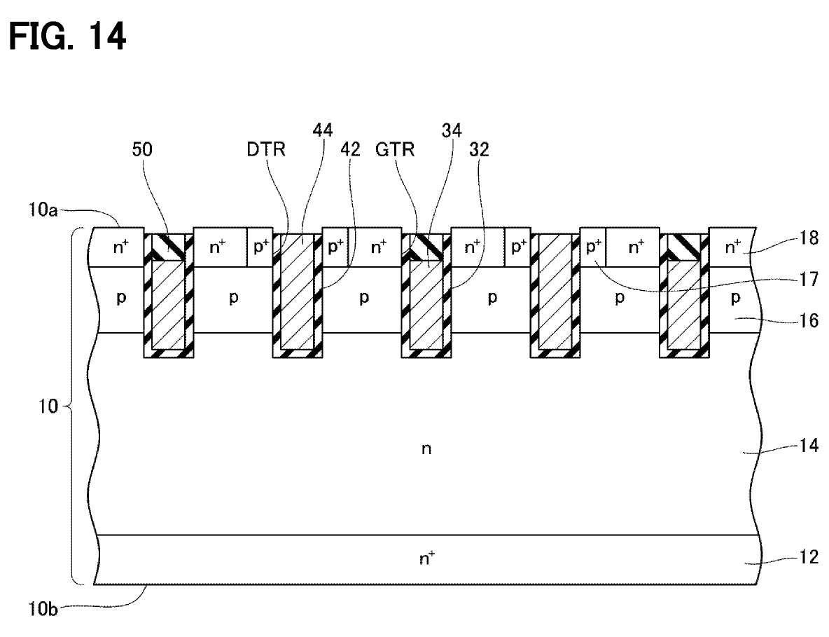

Next, as shown in FIG. 14, the interlayer insulating film 50 and the insulating films 32 and 42 are etched back, for example, using a dry etching technique until the first main surface 10a of the semiconductor layer 10 is exposed. In this etch-back, the interlayer insulating film 50 and the insulating films 32 and 42 may be over-etched to ensure exposure of the first main surface 10a of the semiconductor layer 10. In this case, the interlayer insulating film 50 and the insulating films 32 and 42 after the etch-back are located below the level of the first main surface 10a of the semiconductor layer 10.

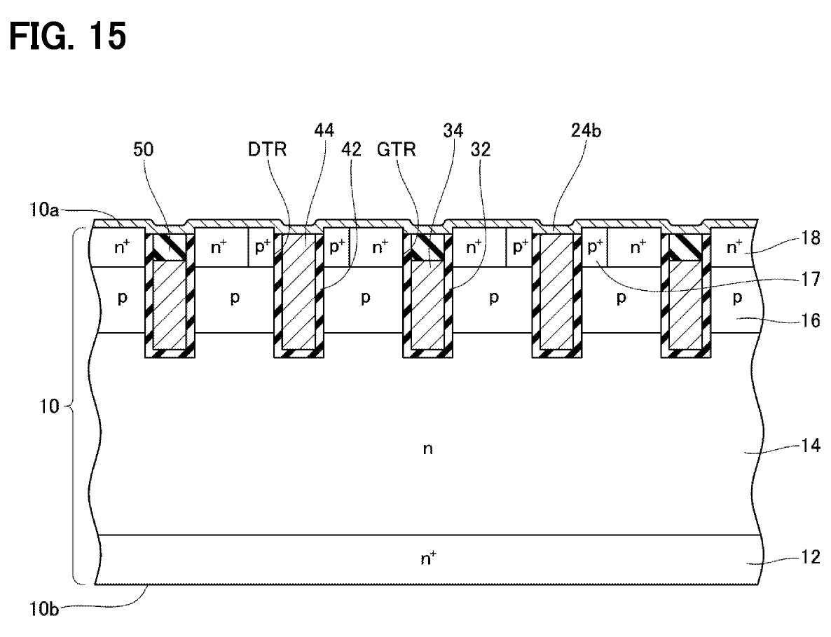

Next, as shown in FIG. 15, a metal layer containing titanium is formed, for example, using a sputtering technique, so as to cover the first main surface 10a of the semiconductor layer 10. Next, by performing annealing at a predetermined temperature, titanium contained in the metal layer is reacted with silicon contained in the semiconductor layer 10 and the dummy electrode 44, so that the metal layer becomes the silicide layer 24b.

Next, a metal electrode layer 24c is formed, for example, using a sputtering technique, so as to cover the first main surface 10a of the semiconductor layer 10. In this way, the source electrode 24 including the silicide layer 24b and the metal electrode layer 24c is formed. Lastly, a drain electrode 22 is formed on a second main surface 10b of the semiconductor layer 10. Thus, the semiconductor device 1 is completed.

In the manufacturing method described above, before the interlayer insulating film 50 is formed, the top surface of the gate electrode 34 is positioned below the level of the top surface of the dummy electrode 44. Thus, the interlayer insulating film 50 can be selectively embedded in the upper portion of the gate trench GTR. In the manufacturing method described above, the dummy trench gate 40 can be incorporated into the semiconductor device having the self-aligned contact structure.

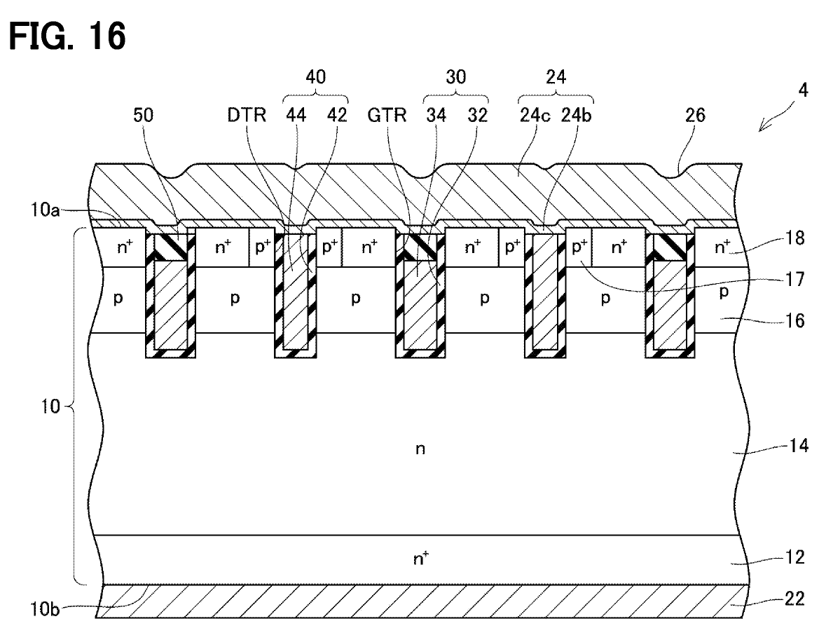

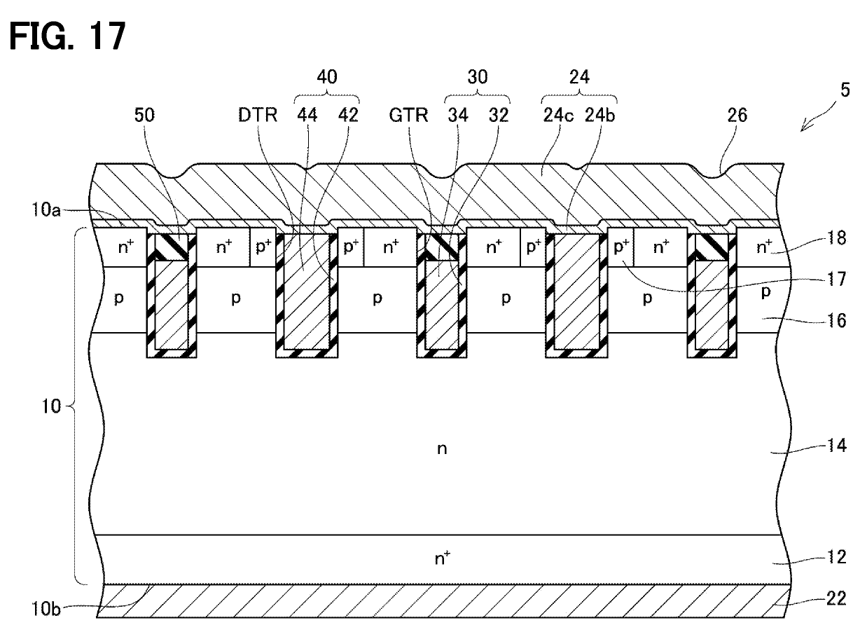

In the embodiment described above, the trench width in a short-side direction of the trench gate 30 and the trench width in a short-side direction of the dummy trench gate 40 are the same. Alternatively, as shown in a semiconductor device 4 of FIG. 16, the trench width of the dummy trench gate 40 may be smaller than the trench width of the trench gate 30. Further, as shown in a semiconductor device 5 of FIG. 17, the trench width of the dummy trench gate 40 may be larger than the trench width of the trench gate 30. The relative relationship between the trench width of the trench gate 30 and the trench width of the dummy trench gate 40 can be appropriately designed depending on specifications. Note that, in the case of the semiconductor device 4 shown in FIG. 16, it is possible to omit the formation of mask shown in FIG. 11. In general, an etching rate of a member embedded in a trench with a small trench width is lowered. For this reason, in a case where the trench width of the dummy trench gate 40 is smaller than the trench width of the trench gate 30, even if the mask 62 has not been formed during the etching shown in FIG. 12, the etching rate of the dummy electrode 44 embedded in the dummy trench DTR is low. Therefore, even if the mask 62 has not been formed during the etching shown in FIG. 12, it is possible to position the top surface of the dummy electrode 44 above the top surface of the gate electrode 34. The semiconductor device 4 shown in FIG. 16 has a structure that can be produced with less number of steps.

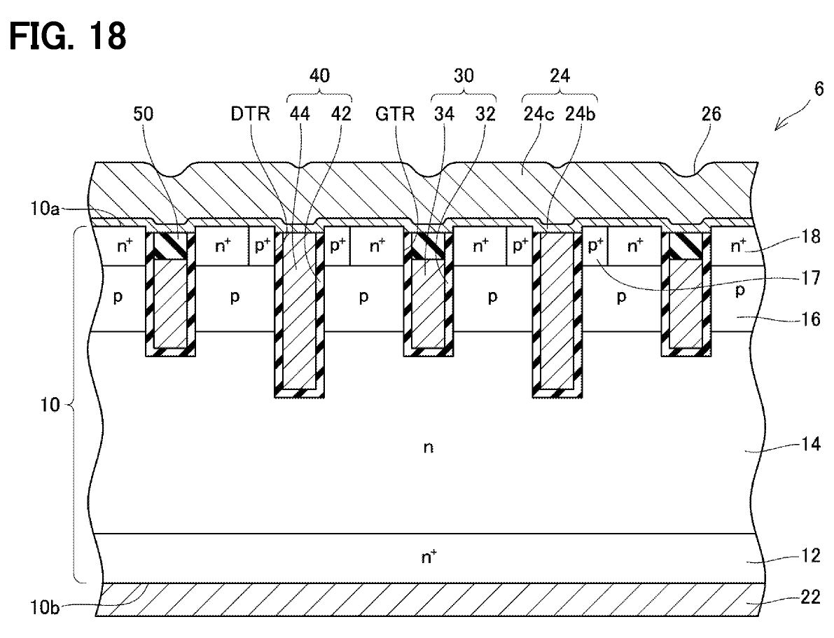

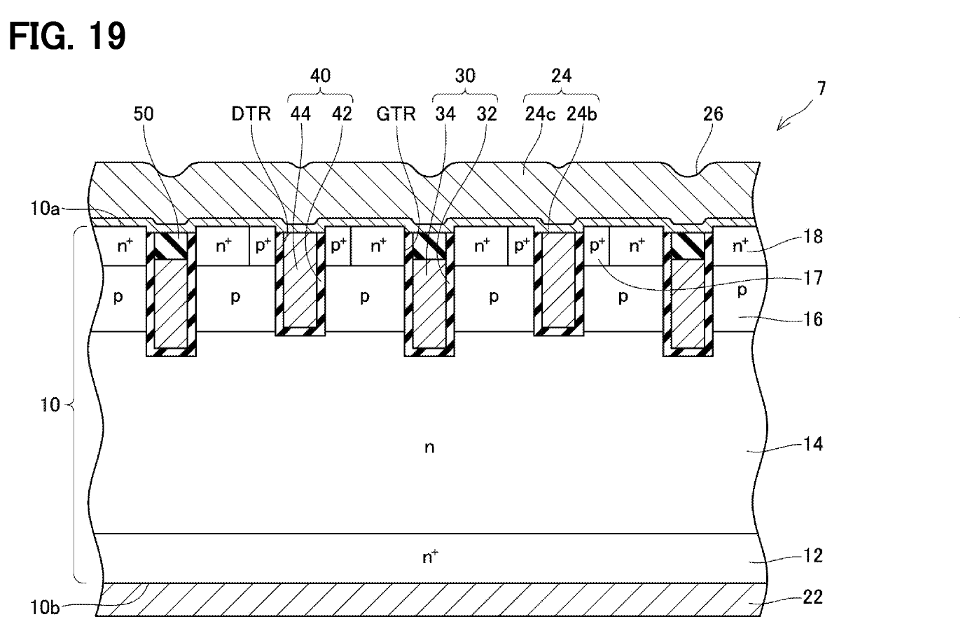

In the embodiments described above, the trench depth of the trench gate 30 and the trench depth of the dummy trench gate 40 are the same. Alternatively, as shown in a semiconductor device 6 of FIG. 18, the trench depth of the dummy trench gate 40 may be deeper than the trench depth of the trench gate 30. Further, as shown in a semiconductor device 7 of FIG. 19, the trench depth of the dummy trench gate 40 may be shallower than the trench depth of the trench gate 30. The relative relationship between the trench depth of the trench gate 30 and the trench depth of the dummy trench gate 40 can be appropriately designed depending on specifications.

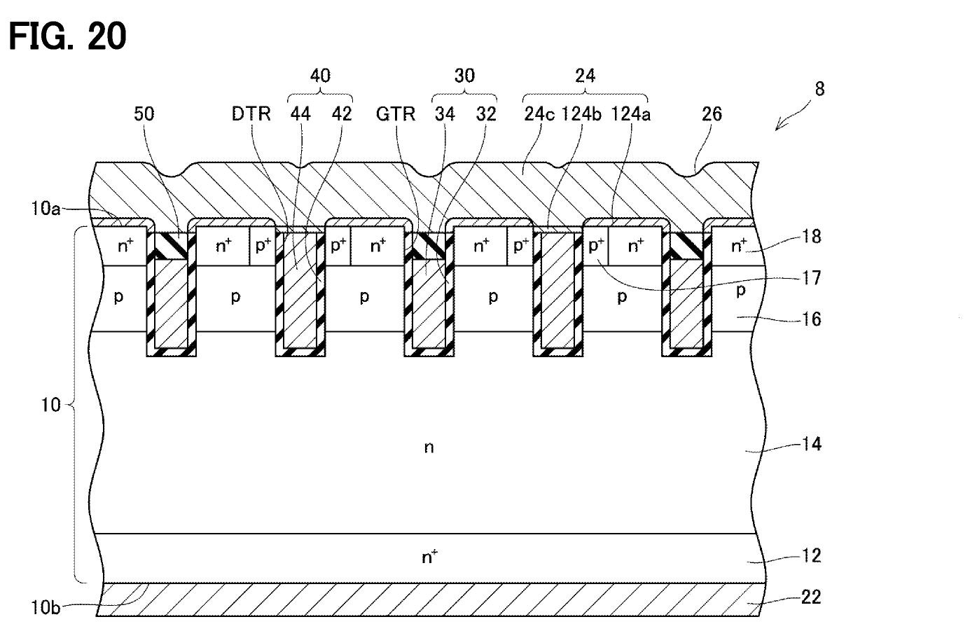

In the embodiment described above, the silicide layer 24b of one type is used in order to enhance the ohmic property of the source electrode 24. As another example, as shown in a semiconductor device 8 of FIG. 20, the silicide layer may be provided by a combination of a first silicide layer 124a and a second silicide layer 124b. The first silicide layer 124a is disposed selectively at a position in contact with the first main surface 10a of the semiconductor layer 10, and is in ohmic contact with the body contact region 17 and the source region 18. More specifically, the first silicide layer 124a is in contact with an upper layer portion of the semiconductor layer 10 excluding the gate trench GTR and the dummy trench DTR, that is, an upper surface of a mesa portion defined between the gate trench GTR and the dummy trench DTR. The first silicide layer 124a is disposed between the first main surface 10a of the semiconductor layer 10 and the metal electrode layer 24c. The first silicide layer 124a may be, for example, made of nickel silicide (NiSi) formed by siliciding nickel (Ni). As another example, the first silicide layer 124a may be, for example, made of a metal silicide formed by siliciding a metal such as tantalum (Ta), tungsten (W), or molybdenum (Mo). The second silicide layer 124b is made of a similar material to the silicide layer 24b containing titanium as in the embodiment described above, and is formed selectively at a position in contact with the dummy electrode 44. Also in the semiconductor device 8, since the second silicide layer 124b containing titanium is disposed at the portion in contact with the dummy electrode 44, particle generation can be suppressed. In addition, in the semiconductor device 8, since the first silicide layer 124a containing nickel is disposed at the portion in contact with the mesa portion of the semiconductor layer 10, contact resistance between the source electrode 24 and the semiconductor layer 10 is low. These silicide layers can be selectively formed, for example, by using sputtering and etching techniques.

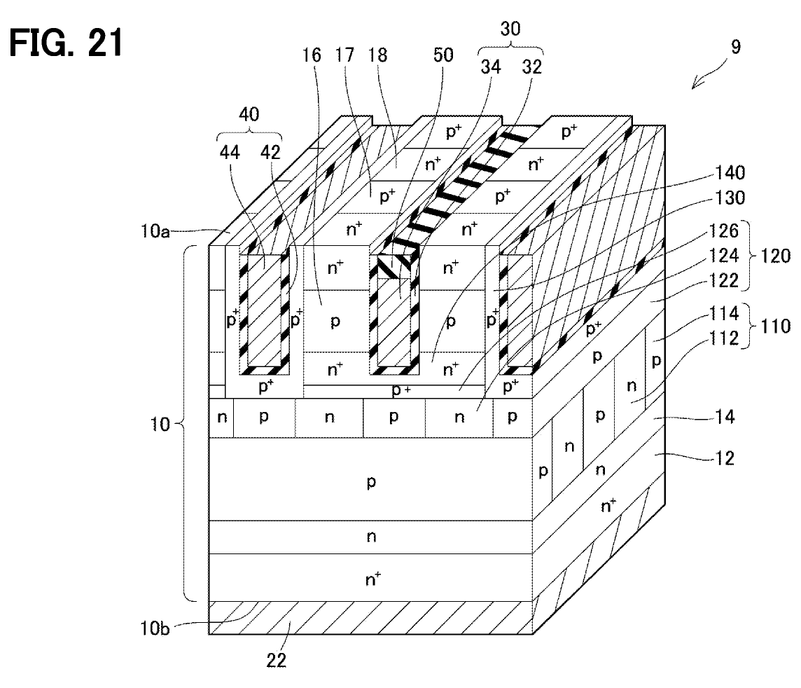

FIG. 21 shows a semiconductor device 9 to which the technique disclosed in this specification is applied. The semiconductor device 9 includes, in addition to components of any embodiment described above, a super junction layer 110, a field relaxation layer 120, a connection layer 130, and a current spreading layer 140.

The super junction layer 110 is a layer disposed so as to be in contact with an upper surface of the drift region 14, and is located between the drift region 14 and the field relaxation layer 120. The super junction layer 110 includes a plurality of n type columns 112 containing an n type impurity and a plurality of p type columns 114 containing a p type impurity. The concentration of the n type impurity in the n type columns 112 is higher than the concentration of the n type impurity in the drift region 14.

Each of the n type columns 112 and the p type columns 114 has a substantially plate-like shape and extends between the drift region 14 and the field relaxation layer 120 along the thickness direction of the semiconductor layer 10. The n type columns 112 and the p type columns 114 may be alternately and repeatedly arranged, for example, along the longitudinal direction of the trench gates 30 and the dummy trench gates 40. Alternatively, the n type columns 112 and the p type columns 114 may be repeatedly arranged in any direction. In the semiconductor device 9 having the super junction layer 110, the on-resistance and breakdown voltage are improved.

The field relaxation layer 120 is a layer disposed so as to be in contact with an upper surface of the super junction layer 110, and is located between the super junction layer 110 and the current spreading layer 140. The field relaxation layer 120 includes a plurality of low-concentration field relaxation regions 122 containing a p type impurity, a plurality of JFET regions 124 containing an n type impurity, and a plurality of high-concentration field relaxation regions 126 containing a p type impurity. The concentration of the p type impurity in the high-concentration field relaxation regions 126 is higher than the concentration of the p type impurity in the low-concentration field relaxation regions 122. Note that, in FIG. 21, only one high-concentration field relaxation region 126, among the plurality of high-concentration field relaxation regions 126, is illustrated.

The low-concentration field relaxation regions 122 and the JFET regions 124 may be alternately and repeatedly arranged along a direction different from the repetition direction of the super junction layer 110, for example, along a direction orthogonal to the repetition direction of the super junction layer 110. Further, each of the plurality of low-concentration field relaxation regions 122 may be disposed below a corresponding trench among the plurality of trench gates 30 and the plurality of dummy trench gates 40. The plurality of high-concentration field relaxation regions 126 are disposed so as to be in contact with upper surfaces of the low-concentration field relaxation regions 122 and the JFET regions 124, and may be disposed spaced apart from each other in a direction different from the repetition direction of the low-concentration field relaxation regions 122 and the JFET regions 124, for example, in a direction orthogonal to the repetition direction of the low-concentration field relaxation regions 122 and the JFET regions 124. Namely, when the semiconductor layer 10 is viewed in plan, that is, in the plan view of the semiconductor layer 10, the plurality of low-concentration field relaxation regions 122 and the plurality of high-concentration field relaxation regions 126 may be arranged in a grid pattern. As described above, the plurality of high-concentration field relaxation regions 126 are dispersedly arranged in a planar direction of the semiconductor layer 10. Therefore, the plurality of high-concentration field relaxation regions 126 do not separate the JFET regions 124 and the current spreading layer 140 in the thickness direction of the semiconductor layer 10. The JFET regions 124 and the current spreading layer 140 are in contact with each other in the thickness direction of the semiconductor layer 10 via regions between the high-concentration field relaxation regions 126. In this manner, the JFET regions 124 connect the n type columns 112 of the super junction layer 110 and the current spreading layer 140 in the thickness direction of the semiconductor layer 10. In the semiconductor device 9 having the field relaxation layer 120, an electric field at bottom surfaces of the trench gates 30 and the dummy trench gates 40 is relaxed.

The connection layer 130 is a region disposed so as to be in contact with side surfaces and a bottom surface of the dummy trench gate 40, and is disposed so as to extend from the first main surface 10a of the semiconductor layer 10, penetrate the body region 16 and the current spreading layer 140, and reach the field relaxation layer 120. The connection layer 130 is a region containing a p type impurity at a high concentration. An upper end portion of the connection layer 130 is in contact with the source electrode 24 and is in ohmic contact with the source electrode 24. Alternatively, the upper end portion of the connection layer 130 may be electrically connected to the source electrode 24 via the body contact region 17. A lower end portion of the connection layer 130 is in contact with the low-concentration field relaxation region 122 and the high-concentration field relaxation regions 126 of the field relaxation layer 120. In this manner, the low-concentration field relaxation regions 122 and the high-concentration field relaxation regions 126 of the field relaxation layer 120 are fixed to a source potential via the connection layer 130.

The current spreading layer 140 is a region disposed so as to be in contact with an upper surface of the field relaxation layer 120, and is located between the field relaxation layer 120 and the body region 16. The current spreading layer 140 is in contact with a lower portion of the side surface and the bottom surface of the trench gate 30, and extends in the planar direction of the semiconductor layer 10. The current spreading layer 140 is a region containing an n type impurity at a high concentration. The concentration of the n type impurity in the current spreading layer 140 is higher than the concentrations of the n type impurity in the drift region 14, the n type columns 112, and the JFET regions 124. Therefore, current flowing through the semiconductor layer 10 can spread in the planar direction of the semiconductor layer 10 due to the current spreading layer 140. In the semiconductor device 9 having the current spreading layer 140, the on-resistance is improved.

Similarly to the other embodiments, the semiconductor device 9 also has the self-aligned contact structure. Therefore, also in the semiconductor device 9, the trench gates 30 and the dummy trench gates 40 can be laid out freely.

In the embodiments described above, the MOSFET has been exemplified; however, the technique disclosed in this specification is also applicable to other types of semiconductor devices including trench-type gates, such as an IGBT (Insulated Gate Bipolar Transistor). In the embodiments described above, an n-channel semiconductor device has been described; however, the technique disclosed in this specification is also applicable to a p-channel semiconductor device.

While only the selected exemplary embodiments and examples have been chosen to illustrate the present disclosure, it will be apparent to those skilled in the art from this disclosure that various changes and modifications can be made therein without departing from the scope of the disclosure as defined in the appended claims. Furthermore, the foregoing description of the exemplary embodiment and examples according to the present disclosure is provided for illustration only, and not for the purpose of limiting the disclosure as defined by the appended claims and their equivalents. Furthermore, the techniques exemplified in this specification or the drawings can achieve multiple purposes at the same time, and achieving one of those purposes itself has technical usefulness.

What is claimed is:

1. A semiconductor device comprising:
a semiconductor layer having a first main surface and a second main surface opposite to the first main surface in a thickness direction of the semiconductor layer, the semiconductor layer including a gate trench and a dummy trench formed in the first main surface;
a trench gate including a gate electrode embedded in the gate trench;
an interlayer insulating film disposed on the gate electrode and embedded in the gate trench;
a dummy trench gate including a dummy electrode embedded in the dummy trench; and
a surface electrode disposed in contact with the first main surface of the semiconductor layer and the dummy electrode embedded in the dummy trench, wherein
a top surface of the dummy electrode is located above a top surface of the gate electrode in the thickness direction of the semiconductor layer.

2. The semiconductor device according to claim 1, wherein:
the semiconductor device comprises a plurality of trench gates including the trench gate, and a plurality of dummy trench gates including the dummy trench gate;
the plurality of trench gates are disposed in the semiconductor layer at the first main surface;
in a plan view when the semiconductor layer is viewed in the thickness direction, the plurality of trench gates extend along a first direction and are spaced apart from each other in a second direction orthogonal to the first direction;
the plurality of dummy trench gates are disposed in the semiconductor layer at the first main surface;
in the plan view, the plurality of dummy trench gates extend along the first direction and are spaced apart from each other in the second direction; and
two or more of the plurality of dummy trench gates are disposed between adjacent ones of the plurality of trench gates in the second direction.

3. The semiconductor device according to claim 1, wherein:
the semiconductor device comprises a plurality of trench gates including the trench gate, and a plurality of dummy trench gates including the dummy trench gate;
the plurality of trench gates are disposed in the semiconductor layer at the first main surface;
in a plan view when the semiconductor layer is viewed in the thickness direction, the plurality of trench gates extend along a first direction and are spaced apart from each other in a second direction orthogonal to the first direction;
the plurality of dummy trench gates are disposed in the semiconductor layer at the first main surface;
in the plan view, the plurality of dummy trench gates extend along the first direction and are spaced apart from each other in the second direction; and
two or more of the plurality of trench gates are disposed between adjacent ones of the plurality of dummy trench gates in the second direction.

4. The semiconductor device according to claim 1, wherein:
the surface electrode has a plurality of recesses formed in an upper surface thereof, the plurality of recesses including a recess located above the gate trench and a recess located above the dummy trench; and
a depressed amount of the recess located above the dummy trench is smaller than a depressed amount of the recess located above the gate trench.

5. The semiconductor device according to claim 1, wherein:
the dummy electrode is made of polysilicon, and
the surface electrode includes a silicide layer containing titanium in a portion that is in contact with the dummy electrode.

6. A method for manufacturing a semiconductor device, the method comprising:
forming a gate trench and a dummy trench in a first main surface of a semiconductor layer, the semiconductor layer having the first main surface and a second main surface opposite to the first main surface in a thickness direction of the semiconductor layer;
embedding a gate electrode and a dummy electrode, respectively, in the gate trench and the dummy trench, so that a top surface of the dummy electrode is located above a top surface of the gate electrode in the thickness direction; and
embedding an interlayer insulating film in the gate trench.

7. The method according to claim 6, wherein
the embedding of the gate electrode and the dummy electrode includes:
filling the gate electrode and the dummy electrode, respectively, in the gate trench and the dummy trench;
forming a mask covering the dummy electrode filled in the dummy trench without covering the gate electrode; and
removing a portion of the gate electrode filled in the gate trench.
